(19) United States
(12) Patent Application Publication
(10) Pub. No.: US 2016/0343993 A1
(43) Pub. Date: Nov. 24, 2016

(54) TRANSPARENT FLEXIBLE PACKAGE SUBSTRATE AND FLEXIBLE OLED PACKAGE METHOD

(71) Applicant: SHENZHEN CHINA STAR OPTOELECTRONICS TECHNOLOGY CO.,LTD., Shenzhen, Guangdong (CN)

(72) Inventors: Qinghua ZOU, Shenzhen, Guangdong (CN); Yifan WANG, Shenzhen, Guangdong (CN)

(73) Assignee: Shenzhen China Star Optoelectronics Technology Co., Ltd., Shenzhen, Guangdong (CN)

(21) Appl. No.: 14/424,536

(22) PCT Filed: Feb. 9, 2015
(86) PCT No.: PCT/CN2015/072496

§ 371 Date: Feb. 27, 2015

(30) Foreign Application Priority Data
Dec. 17, 2014 (CN) 201410789952.6

(51) Int. Cl. H01L 51/56; H01L 51/00; B32B 17/06; H01L 51/52

(52) U.S. Cl. CPC H01L 51/56; H01L 51/5259; H01L 51/5246; H01L 51/0097; B32B 17/064; B32B 2307/206; B32B 2457/206

(57) ABSTRACT

The present invention provides a transparent flexible package substrate and a flexible OLED package method, comprising: a flexible glass (2), an insulative glue layer (1) located at one side of the flexible glass (2), a polymer layer (3) located at the other side of the flexible glass (2); a surface dimension of the flexible glass (2) is larger than a surface dimension of the polymer layer (3); a surface dimension of the flexible glass (2) is smaller than or equal to a surface dimension of the insulative glue layer (1). The transparent flexible package substrate possesses well flexibility and properties of excellent anti-water, anti-oxygen abilities, and manufactured with flexible glass material, which is a transparent flexible package substrate capable of being widely utilized and applicable for packages of many kinds of OLED display elements.

### FIELD OF THE INVENTION

The present invention relates to a display technology field, and more particularly to a transparent flexible package substrate and a flexible OLED package method.

### BACKGROUND OF THE INVENTION

The flat panel display elements possess many merits of thin frame, power saving, no radiation, etc. and have been widely used. The present flat panel display elements at present mainly comprise the Liquid Crystal Display (LCD) and the Organic Light Emitting Display (OLED).

The OLED display element with the advantages of self-lighting, all solid state, high contrast, etc. has become the most potential new type display element in recent years. The biggest distinguishing feature of the OLED display element is capable of realizing the flexible display. It is an important development direction of the OLED display element to employ flexible substrate to manufacture light weight, bendable, portable flexible display element.

The traditional OLED display element utilizes hard glass substrate which can have low penetrability for oxygen and water vapor and protect the element better. The flexible substrate mainly employed for the flexible Organic Light Emitting Display element is the polymer substrate. The polymer substrate is light and thin, firm but with excellent flexibility. However, the polymer substrate itself has smaller free volume fraction and larger chain-segment average free degree. It is the destiny which can be easily penetrated by water and oxygen and shorten the lifetime of the Organic Light Emitting Display element.

When the thickness of the metal material reaches down below 100 um, it can possess excellent flexibility. Compared with polymer, the heat resistance is great and the coefficient of thermal expansion is very low. Particularly, there is no water and oxygen permeation issue, which is very suitable for being the substrate material of the flexible organic emitting light element. As shown in FIG. 1, a polymer-metal complex flexible package substrate according to prior art comprises a first polymer layer 10, a metal foil 20 located on the first polymer layer 10, a second polymer layer 30 located on the metal foil 20. A surface dimension of the metal foil 20 is larger than surface dimensions of the first polymer layer 10 and the second polymer layer 30, which diminishes the influence of the external environment to the packaged element and extends the lifetime of the element. Besides, the manufacture process is simple, and the cost is lower. However, the flexible substrate manufactured with metal material is not transparent, which restricts its application field. Willow Glass is a new kind of glass material. Compared with the meal material, the Willow Glass material similarly possesses great flexibility, anti-water, anti-oxygen abilities and is transparent material.

### SUMMARY OF THE INVENTION

An objective of the present invention is to provide a transparent flexible package substrate, applied for the package of the flexible OLED and equipped with well flexibility and excellent anti-water, anti-oxygen abilities, which utilizes transparent material for manufacture to expand the application field.

An objective of the present invention is to provide a flexible OLED package method, which utilizes the transparent flexible package substrate provided by the present invention for package, capable of realizing well flexibility, and properties of excellent anti-water, anti-oxygen abilities and transparency and can be applied for packages of many kinds of OLED display elements.

For realizing the aforesaid objective, the present invention first provides a transparent flexible package substrate, comprising: a flexible glass, an insulative glue layer located at one side of the flexible glass, a polymer layer located at the other side of the flexible glass;

a surface dimension of the flexible glass is larger than a surface dimension of the polymer layer;

a surface dimension of the flexible glass is smaller than or equal to a surface dimension of the insulative glue layer.

A thickness of the flexible glass is smaller than 100 um.

A thickness of the polymer layer is 5-100 um.

A main material of the polymer layer is polyimide, polycarbonate, polyethylene glycol terephthalate, Polyethylene Naphthalate or polyether sulphone, which is filled with dryer.

A main material of the insulative glue layer is acrylic resin body or epoxy resin body, which is filled with nano fibers or nano particles.

The present invention further provides a flexible OLED package method, comprising:

step 1, providing a flexible glass, and forming a polymer layer laden with dryer at one side of the flexible glass;

step 2, forming an insulative glue layer containing nano fibers or nano particles at the other side of the flexible glass to form a transparent flexible package substrate;

step 3, coating a number of strips of flexible package glue at one side of the transparent flexible package substrate with the polymer layer, or directly coating flexible package glue on the entire surface of the other side of the transparent flexible package substrate with the polymer layer;

step 4, oppositely assembling a manufactured flexible OLED substrate and the transparent flexible package substrate, wherein an OLED element is located corresponding to the polymer layer, and the flexible OLED substrate is adhered on the transparent flexible package substrate via the flexible package glue, and UV curing or thermal curing the flexible package glue to form a sealed flexible display device.

A specific step of step 1 is: directly adhering a polymer layer laden with dryer at one side of the flexible glass, or: coating polymer precursor solution laden with dryer at one side of the flexible glass, and curing the same to form the polymer layer; a main material of the polymer layer is polyimide, polycarbonate, polyethylene glycol terephthalate, Polyethylene Naphthalate or polyether sulphone, which is filled with dryer.

A specific step of step 2 is: directly adhering an insulative glue layer containing nano fibers or nano particles at the other side of the flexible glass, or: coating insulative glue material containing nano fibers or nano particles at the other side of the flexible glass, and curing the same to form the insulative glue layer; a main material of the insulative glue layer is acrylic resin body or epoxy resin body, which is filled with nano fibers or nano particles.

A thickness of the flexible glass provided in the step 1 is smaller than 100 um, and a thickness of the polymer layer is 5-100 um.

The OLED display substrate provided in the step 4 comprises a flexible substrate and an OLED lighting element located on the flexible substrate.

The present invention further provides a transparent flexible package substrate, comprising: a flexible glass, an insulative glue layer located at one side of the flexible glass, a polymer layer located at the other side of the flexible glass;

a surface dimension of the flexible glass is larger than a surface dimension of the polymer layer;

a surface dimension of the flexible glass is smaller than or equal to a surface dimension of the insulative glue layer;

wherein a thickness of the flexible glass is smaller than 100 um;

wherein a thickness of the polymer layer is 5-100 um.

The benefits of the present invention are: the present invention provides a transparent flexible package substrate, and the transparent flexible package substrate possesses well flexibility and properties of excellent anti-water, anti-oxygen abilities, and manufactured with flexible glass material, which is a transparent flexible package substrate and widely applied in many aspects. The present invention further provides a flexible OLED package method, which utilizes the transparent flexible package substrate provided by the present invention for package, capable of employing well flexibility, and properties of excellent anti-water, anti-oxygen abilities and transparency and can be applied for packages of many kinds of OLED display elements and widely applied in many aspects.

In order to better understand the characteristics and technical aspect of the invention, please refer to the following detailed description of the present invention is concerned with the diagrams, however, provide reference to the accompanying drawings and description only and is not intended to be limiting of the invention.

### BRIEF DESCRIPTION OF THE DRAWINGS

The technical solution and the beneficial effects of the present invention are best understood from the following detailed description with reference to the accompanying figures and embodiments.

In drawings,

FIG. 1 is a structural diagram of polymer-metal complex flexible package substrate according to prior art.

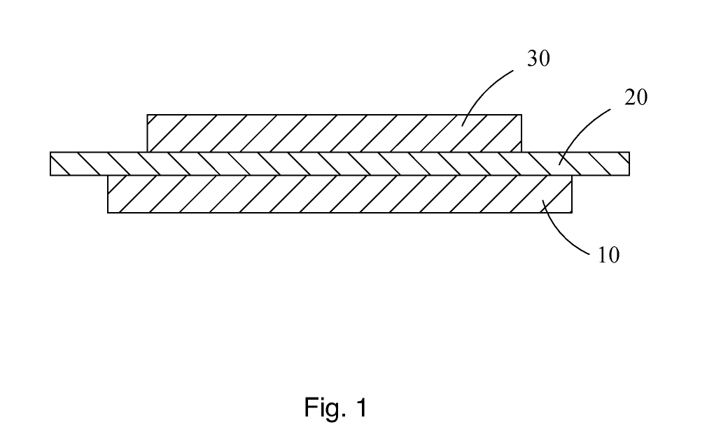

FIG. 2 is a structural diagram of a transparent flexible package substrate according to the present invention;

FIG. 3 is a flowchart of a flexible OLED package method according to the present invention;

FIG. 4 is a structural diagram of a flexible OLED package method according to the first embodiment of the present invention;

FIG. 5 is a structural diagram of a flexible OLED package method according to the second embodiment of the present invention.

### DETAILED DESCRIPTION OF PREFERRED EMBODIMENTS

For better explaining the technical solution and the effect of the present invention, the present invention will be further described in detail with the accompanying drawings and the specific embodiments.

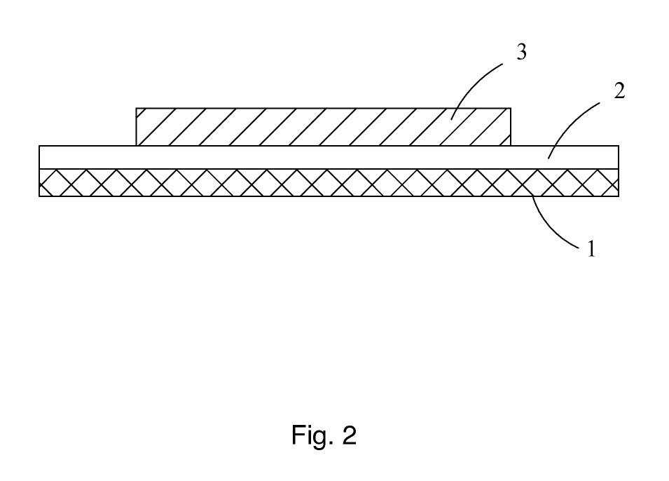

Please refer to FIG. 2. The present invention provides a transparent flexible package substrate, comprising: a flexible glass 2, an insulative glue layer 1 located at one side of the flexible glass 2, a polymer layer 3 located at the other side of the flexible glass 2;

a surface dimension of the flexible glass 2 is larger than a surface dimension of the polymer layer 3;

a surface dimension of the flexible glass 2 is smaller than or equal to a surface dimension of the insulative glue layer 1.

Specifically, the thickness of the flexible glass 2 is smaller than 100 um and preferably, the thickness of the flexible glass 2 is 30-60 um.

A main material of the polymer layer 3 is polyimide, polycarbonate, polyethylene glycol terephthalate, Polyethylene Naphthalate or polyether sulphone, which is filled with dryer. Furthermore, a thickness of the polymer layer 3 is 5-100 um.

A main material of the insulative glue layer 1 is acrylic resin body or epoxy resin body, which is filled with nano fibers or nano particles, capable of enhancing the strength of the entire transparent flexible package substrate.

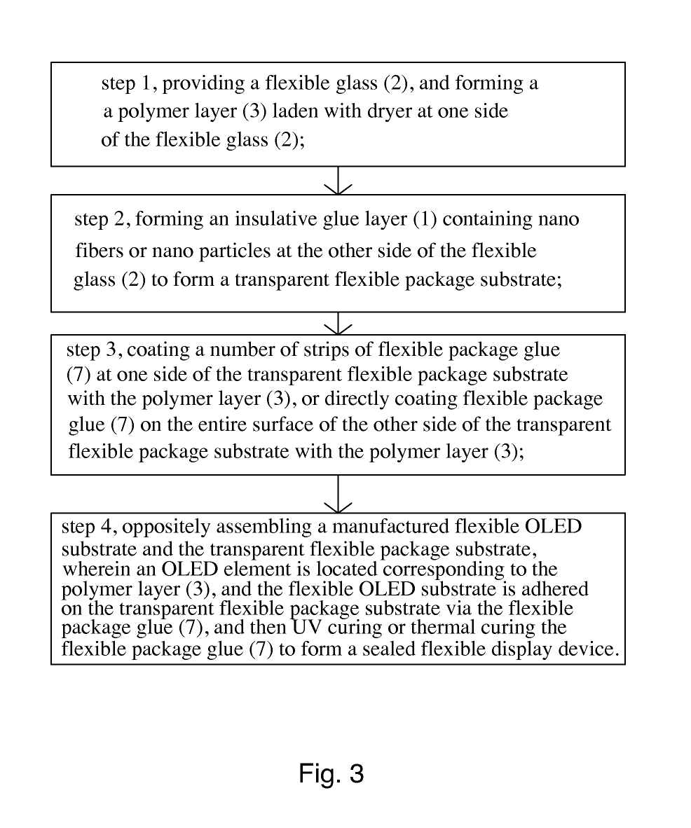

Refer to FIGS. 3-5, the present invention further provides an OLED package method, comprising steps of:

step 1, providing a flexible glass 2, and forming a polymer layer 3 laden with dryer at one side of the flexible glass 2;

Specifically, the thickness of the flexible glass 2 is smaller than 100 um and preferably to be 30-60 um;

A specific step of step 1 is: directly adhering a polymer layer 3 laden with dryer at one side of the flexible glass 2, or: coating polymer precursor solution laden with dryer at one side of the flexible glass 2, and curing the same to form the polymer layer 3; a main material of the polymer layer 3 is polyimide, polycarbonate, polyethylene glycol terephthalate, Polyethylene Naphthalate or polyether sulphone, which is filled with dryer. A thickness of the polymer layer 3 is 5-100 um.

step 2, forming an insulative glue layer 1 containing nano fibers or nano particles at the other side of the flexible glass 2 to form a transparent flexible package substrate;

a specific step of step 2 is: directly adhering an insulative glue layer 1 containing nano fibers or nano particles at the other side of the flexible glass 2, or: coating insulative glue material containing nano fibers or nano particles at the other side of the flexible glass 2, and curing the same to form the insulative glue layer 1; a main material of the insulative glue layer 1 is acrylic resin body or epoxy resin body, which is filled with nano fibers or nano particles.

Filling nano fibers or nano particles in the insulative glue layer 1 can enhance the strength of the entire transparent flexible package substrate in advance.

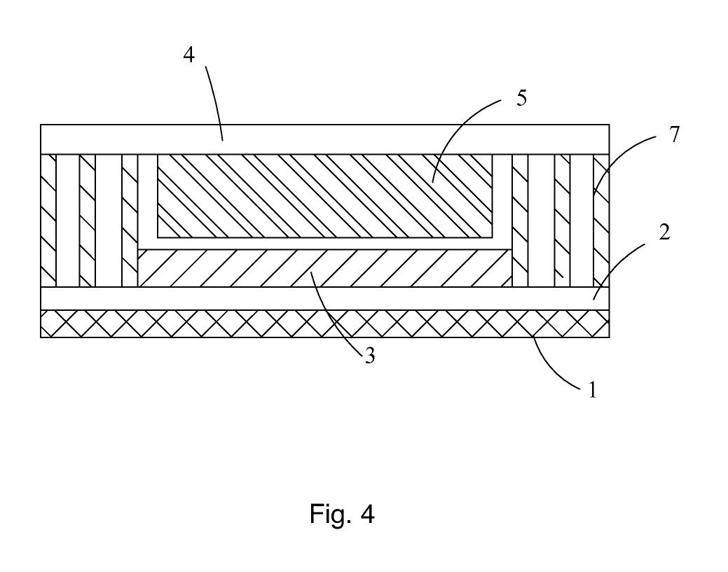

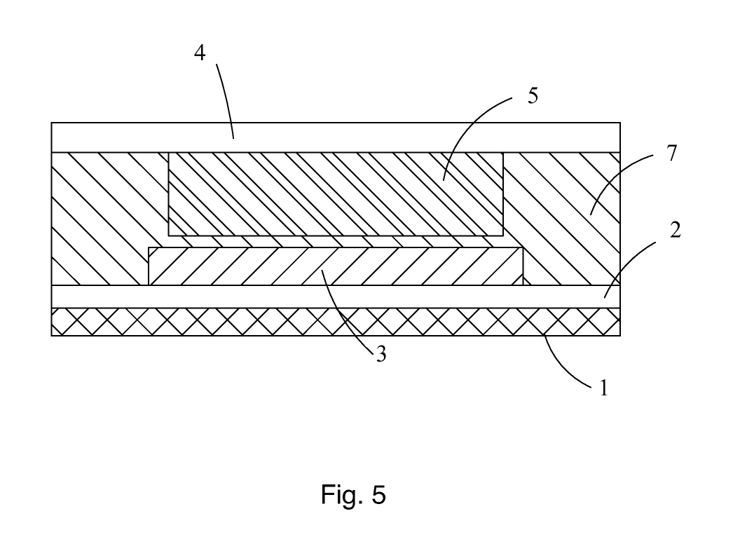

step 3, as shown in FIG. 4, coating a number of strips of flexible package glue 7 at one side of the transparent flexible package substrate with the polymer layer 3, or as shown in FIG. 5, directly coating flexible package glue 7 on the entire surface of the other side of the transparent flexible package substrate with the polymer layer 3;

step 4, oppositely assembling a manufactured flexible OLED substrate and the transparent flexible package substrate, wherein an OLED element is located corresponding to the polymer layer 3, and the flexible OLED substrate is adhered on the transparent flexible package substrate via the flexible package glue 7, and then UV curing or thermal curing the flexible package glue 7 to form a sealed flexible display device.

The OLED display substrate provided in the step 4 comprises a flexible substrate 4 and an OLED lighting element 5 located on the flexible substrate. The package substrate is a transparent flexible package substrate, thus, the OLED element 6 can be top emitting or bottom emitting types which can be selectable on demands and not limited to be the package substrate.

In conclusion the present invention provides a transparent flexible package substrate possessing well flexibility and properties of excellent anti-water, anti-oxygen abilities, and manufactured with flexible glass material, which is a transparent flexible package substrate capable of being widely utilized. The present invention further provides a flexible OLED package method, which utilizes the transparent flexible package substrate provided by the present invention for package, capable of employing well flexibility, and properties of excellent anti-water, anti-oxygen abilities and transparency and can be applied for packages of many kinds of OLED display elements.

Above are only specific embodiments of the present invention, the scope of the present invention is not limited to this, and to any persons who are skilled in the art, change or replacement which is easily derived should be covered by the protected scope of the invention. Thus, the protected scope of the invention should go by the subject claims.

What is claimed is:

1. A transparent flexible package substrate, comprising: a flexible glass, an insulative glue layer located at one side of the flexible glass, a polymer layer located at the other side of the flexible glass;
a surface dimension of the flexible glass is larger than a surface dimension of the polymer layer;
a surface dimension of the flexible glass is smaller than or equal to a surface dimension of the insulative glue layer.

2. The transparent flexible package substrate according to claim 1, wherein a thickness of the flexible glass is smaller than 100 um.

3. The transparent flexible package substrate according to claim 1, wherein a thickness of the polymer layer is 5-100 um.

4. The transparent flexible package substrate according to claim 3, wherein a main material of the polymer layer is polyimide, polycarbonate, polyethylene glycol terephthalate, Polyethylene Naphthalate or polyether sulphone, which is filled with dryer.

5. The transparent flexible package substrate according to claim 1, wherein a main material of the insulative glue layer is acrylic resin body or epoxy resin body, which is filled with nano fibers or nano particles.

6. A flexible OLED package method, comprising steps of:
step 1, providing a flexible glass, and forming a polymer layer laden with dryer at one side of the flexible glass;
step 2, forming an insulative glue layer containing nano fibers or nano particles at the other side of the flexible glass to form a transparent flexible package substrate;
step 3, coating a number of strips of flexible package glue at one side of the transparent flexible package substrate with the polymer layer, or directly coating flexible package glue on the entire surface of the other side of the transparent flexible package substrate with the polymer layer;
step 4, oppositely assembling a manufactured flexible OLED substrate and the transparent flexible package substrate, wherein an OLED element is located corresponding to the polymer layer, and the flexible OLED substrate is adhered on the transparent flexible package substrate via the flexible package glue, and UV curing or thermal curing the flexible package glue to form a sealed flexible display device.

7. The flexible OLED package method according to claim 6, wherein a specific step of step 1 is: directly adhering a polymer layer laden with dryer at one side of the flexible glass, or: coating polymer precursor solution laden with dryer at one side of the flexible glass, and curing the same to form the polymer layer; a main material of the polymer layer is polyimide, polycarbonate, polyethylene glycol terephthalate, Polyethylene Naphthalate or polyether sulphone, which is filled with dryer.

8. The flexible OLED package method according to claim 6, wherein a specific step of step 2 is: directly adhering an insulative glue layer containing nano fibers or nano particles at the other side of the flexible glass, or: coating insulative glue material containing nano fibers or nano particles at the other side of the flexible glass, and curing the same to form the insulative glue layer; a main material of the insulative glue layer is acrylic resin body or epoxy resin body, which is filled with nano fibers or nano particles.

9. The flexible OLED package method according to claim 6, wherein a thickness of the flexible glass provided in the step 1 is smaller than 100 um, and a thickness of the polymer layer is 5-100 um.

10. The flexible OLED package method according to claim 6, wherein the OLED display substrate provided in the step 4 comprises a flexible substrate and an OLED lighting element located on the flexible substrate.

11. A transparent flexible package substrate, comprising: a flexible glass, an insulative glue layer located at one side of the flexible glass, a polymer layer located at the other side of the flexible glass;
a surface dimension of the flexible glass is larger than a surface dimension of the polymer layer;
a surface dimension of the flexible glass is smaller than or equal to a surface dimension of the insulative glue layer;
wherein a thickness of the flexible glass is smaller than 100 um;
wherein a thickness of the polymer layer is 5-100 um.

12. The transparent flexible package substrate according to claim 11, wherein a main material of the polymer layer is polyimide, polycarbonate, polyethylene glycol terephthalate, Polyethylene Naphthalate or polyether sulphone, which is filled with dryer.

13. The transparent flexible package substrate according to claim 11, wherein a main material of the insulative glue layer is acrylic resin body or epoxy resin body, which is filled with nano fibers or nano particles.
